(19) United States
(12) Patent Application Publication
(10) Pub. No.: US 2010/0109732 A1
(43) Pub. Date: May 6, 2010

(54) INTEGRATED CIRCUIT, CONTROL METHOD, AND USE OF A CIRCUIT FOR A SLEEP MODE AND AN OPERATING MODE

(76) Inventors: Lutz DATHE, Dresden (DE); Matthias Vorwerk, Dresden (DE); Thomas Hanusch, Coswig (DE)

Correspondence Address: Muncy, Geissler, Olds & Lowe, PLLC, P.O. BOX 1364, FAIRFAX, VA, 22038-1364, US

(21) Appl. No.: 12/607,607

(22) Filed: Oct. 28, 2009

Related U.S. Application Data
(60) Provisional application No. 61/117,384, filed on Nov. 24, 2008.

(30) Foreign Application Priority Data
Oct. 28, 2008 (DE) DE 102008053533.8

(51) Int. Cl. H03K 3/02; H01L 25/00

(52) U.S. Cl. 327/198; 327/530

(57) ABSTRACT

A circuit, control method, and use of a circuit for a sleep mode and an operating mode with a digital CMOS circuit with NMOS field-effect transistors and with PMOS field-effect transistors, with a first load device, whereby source terminals of the NMOS field-effect transistors of the digital CMOS circuit are connected via the first load device to a first supply voltage, and with a second load device, whereby source terminals of the PMOS field-effect transistors of the digital CMOS circuit are connected via the second load device to a second supply voltage, wherein the body terminals of the NMOS field-effect transistors of the digital CMOS circuit are connected directly to the first supply voltage, and the body terminals of the PMOS field-effect transistors of the digital CMOS circuit are connected directly to the second supply voltage.

This nonprovisional application claims priority to German Patent Application No. DE 10 2008 053 533.8, which was filed in Germany on Oct. 28, 2008, and to U.S. Provisional Application No. 61/117,384, which was filed on Nov. 24, 2008, and which are both herein incorporated by reference.

### BACKGROUND OF THE INVENTION

1. Field of the Invention

The present invention relates to an integrated circuit, a control method, and a use of a circuit for a sleep mode and an operating mode.

2. Description of the Background Art

Various circuits that enable operation in a sleep mode and in an operating mode are known from the state of the art. In the sleep mode, the current consumption of the circuit is reduced compared with the operating mode. For example, so-called watchdogs, which activate or deactivate a digital circuit and can switch it to one or more sleep modes and to one or more operating modes, are used to this end. If a circuit is needed for the operation of a function, it is shifted from a sleep mode to an operating mode associated with the function.

### SUMMARY OF THE INVENTION

It is therefore an object of the present invention to provide an integrated circuit with properties improved as much as possible for a sleep mode.

Accordingly, a circuit is provided. The circuit can be integrated monolithically on a semiconductor chip. The integrated circuit has a digital CMOS circuit with NMOS field-effect transistors and with PMOS field-effect transistors. MOS field-effect transistors (MOS: metal-oxide semiconductor) have a source, a drain, a gate, and a body (trough/substrate), which is also called a bulk. NMOS field-effect transistors in this case are of the n-conducting type, whereas PMOS field-effect transistors are of the p-conducting type. In the digital CMOS circuit, the NMOS field-effect transistors and PMOS field-effect transistors are used as complementary types. In this case, in a basic logic function, such as, for example, a gate, each NMOS field-effect transistor is assigned at least one PMOS field-effect transistor and each PMOS field-effect transistor is assigned at least one NMOS field-effect transistor.

The circuit can have a first load device and a second load device. The first load device can be connected to a first supply voltage and to the source terminals of the NMOS field-effect transistors of the digital CMOS circuit. The second load device can be connected to a second supply voltage and to the source terminals of the PMOS field-effect transistors of the digital CMOS circuit. A load device in this case is taken to mean a circuit component that represents a load for a current flowing through said component and causes a voltage drop across the load. Preferably, the load device has a current voltage characteristic, which is assigned to a linear or nonlinear course.

Body terminals of the NMOS field-effect transistors of the digital CMOS circuit can be connected directly to the first supply voltage (conductively). Accordingly, no component, particularly no component with a resistor, is provided between the body terminals of the NMOS field-effect transistors and the first supply voltage. For example, the body terminals of the NMOS field-effect transistors are connected to the supply voltage via a conductor, particularly a metal conductor. This also applies to the body terminals of the PMOS transistors of the digital CMOS circuit, which are connected directly to the second supply voltage.

The object of the invention furthermore is to provide as improved a method as possible for controlling a circuit.

Accordingly, a method is provided for a circuit with MOS field-effect transistors for controlling the same in an operating mode and in a sleep mode with a current consumption that is reduced compared with the operating mode. In this regard, multiple sleep modes and/or multiple operating modes may also be provided. In the operating mode, a load device connected to source terminals of the MOS field-effect transistors is controlled to a low-resistance state. In the low-resistance state, a voltage drop across the load device can be disregarded in regard to circuit function. For example, the control of the low-resistance state can be effected by a switching on of a switching transistor.

In the sleep mode, the load device is controlled to a state with a higher resistance value compared with the operating mode. The load device, in this case, is controlled in such a way that a leakage current, flowing through the MOS field-effect transistors and through the load device in the sleep mode, produces a voltage drop across the load device.

The object of the invention furthermore is to provide a use of a circuit for a sleep mode and an operating mode.

Accordingly, a use of a circuit for a sleep mode and an operating mode is provided. The circuit has a number of MOS field-effect transistors whose body terminals are connected to a supply voltage.

The circuit furthermore has a load device which is connected to the source terminals of the MOS field-effect transistors and to the supply voltage.

The circuit in this regard is formed in such a way that it is controllable in the operating mode and in the sleep mode. In so doing, the sleep mode is notable for a current consumption that is reduced compared with the operating mode.

The load device, in this case, is formed in such a way that a leakage current flowing through the MOS field-effect transistors and through the load device in the sleep mode produces a voltage drop across the load device.

Another aspect of the invention is a use of a load device to produce a body-source voltage at the MOS field-effect transistors of a circuit. To this end, the load device is connected to the source terminals of the MOS transistors of the circuit. The body-source voltage is generated in a sleep mode of the circuit. A leakage current flowing through the MOS field-effect transistors and through the load device causes the voltage drop at the load device. Because of the connections of the load device to the MOS field-effect transistors, this voltage drop produces a body-source voltage at the source terminals and body terminals of the MOS field-effect transistors.

In a further embodiment, the first load device is configured to generate a first voltage drop via only a leakage current that flows through the digital CMOS circuit and the first load device, and the second load device is configured to generate a second voltage drop via only a leakage current that flows through the digital CMOS circuit and the second load device.

The embodiments described hereinafter relate to the circuit, as well as to the use and to the control method.

According to an embodiment, it is provided that the circuit has NMOS transistors and PMOS transistors, which form a digital CMOS circuit. The circuit in this regard has a first load device which is connected to the source terminals of the NMOS transistors and to a first supply voltage. The circuit furthermore has a second load device which is connected to the source terminals of the PMOS field-effect transistors and to a second supply voltage. Preferably, a voltage drop across the first load device and/or the second load device produces a higher source potential of the NMOS field-effect transistors, compared with the body potential, and/or a lower source potential of the PMOS field-effect transistors, compared with the body potential.

According to an embodiment, the digital CMOS circuit is formed for an operating mode and for a sleep mode. In the operating mode, the digital CMOS circuit is formed to perform various operating functions. For example, in this case, the digital CMOS circuit performs calculations, writes information in the memory or the register, or reads the appropriate information out of memory cells. In the operating mode, a clock signal can be applied to the digital CMOS circuit. In contrast, the digital CMOS circuit preferably performs no operations in the sleep mode.

It is provided, however, that in the sleep mode all digital elements, such as gates or memory elements and the like, have a defined state. A defined state of this type is a logic one or logic zero at the output of the respective element. The digital CMOS circuit in this case can work together with another digital CMOS circuit, which in the sleep mode is completely disconnected from the first supply voltage and the second supply voltage and therefore cannot have defined states.

In another embodiment, the first load device and the second load device each have a variable resistance device. A resistance device of this type is advantageously a switchable resistor, such as, for example, an ohmic resistor, which can be turned on and off by a transistor. Alternatively, a variable (active) resistor in the form of a field-effect transistor can also be used as a switchable resistor, whose drain-source path can be varied between (at least) two resistance values. For example, a continuous change in the resistance value or switching between several discrete resistance values is possible.

The variable resistance device can have at least one field-effect transistor. As an alternative to a variable resistance device, a component can also be used as the first and/or second load device; in the sleep mode because of the low leakage current said component has a high resistance value and in the operating mode because of the high operating current a significantly lower resistance value. In this case, the first and/or second load device would adjust its resistance independently.

In another embodiment, it is provided that the variable resistance device has a nonlinear resistance value at least in a sleep mode. Accordingly, the current voltage characteristic of the variable resistance device deviates from a straight line. Preferably, the resistance device has a field-effect transistor, so that the resistance value is formed by the characteristic of the field-effect transistor, whereby a gate terminal and a drain terminal of the field-effect transistor can be or are connected conductively to one another. In order to connect the gate terminal and the drain terminal of the field-effect transistor conductively with one another, another field-effect transistor is preferably provided whose drain-source path represents the connection.

In a further embodiment, it is provided that the variable resistance device has a resistance element and a switching element connected parallel to the resistance element. The switching element is, for example, a field-effect transistor. The resistance element is, for example, an ohmic resistor or a variable (active) resistor whose resistance value is fixedly set, for example, by its wiring. In the sleep mode, the resistance element acts in series to the digital CMOS circuit, so that a leakage current through the digital CMOS circuit causes a voltage drop across the resistance element. In contrast, the switching element short-circuits the resistance element in the operating mode, so that the operating current flows across the switching element.

According to an embodiment, the first and the second load device can have a higher resistance value in the sleep mode than in the operating mode. If multiple sleep modes are provided, in a refinement of the invention, the resistance value of the different sleep modes can be adjusted in each case.

An embodiment provides that the digital circuit can have a number of memory elements and/or a number of logic elements. Memory elements of this type are, for example, flip-flops or latches or the like. The logic elements are, for example, gates or the like. The memory elements and the first load device and the second load device are thereby formed in such a way that the information in the memory elements is retained in the sleep mode. The logic elements and the first load device and the second load device are thereby formed in such a way that the logic elements retain defined logic states in the sleep mode.

The digital circuit particularly with the memory elements and the first and the second load device can be connected in series. In this case, the leakage current flows across the first load device and generates a first voltage drop in the first load device. The leakage current flows further through the digital circuit and finally through the second load device and there also produces a second voltage drop. The first load device and the second load device and the memory elements in this case must be formed in such a way that the available supply voltages less the voltage drop across the first load device and of the voltage drop across the second load device produce a sufficient holding voltage across the digital circuit; in this regard, the holding voltage is sufficiently high so that the memory elements retain a defined state, therefore a logic one or a logic zero.

The previously described embodiments are especially advantageous both individually and in combination. In this regard, all refinement variants can be combined with one another. Some possible combinations are explained in the description of the exemplary embodiments shown in the figures. These possible combinations of the refinement variants, depicted therein, are not definitive, however.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a shows a schematic cross section through a MOS field-effect transistor;

FIG. 1b shows a schematic course of a characteristic of a MOS field-effect transistor;

FIG. 2a shows a basic circuit diagram of a load device;

FIG. 2b shows another basic circuit diagram of a load device;

FIG. 3 shows a schematic circuit with a simplified digital CMOS circuit;

FIG. 4a shows a schematic drawing of a resistance device; and

FIG. 4b shows a schematic drawing of an alternative resistance device.

### DETAILED DESCRIPTION

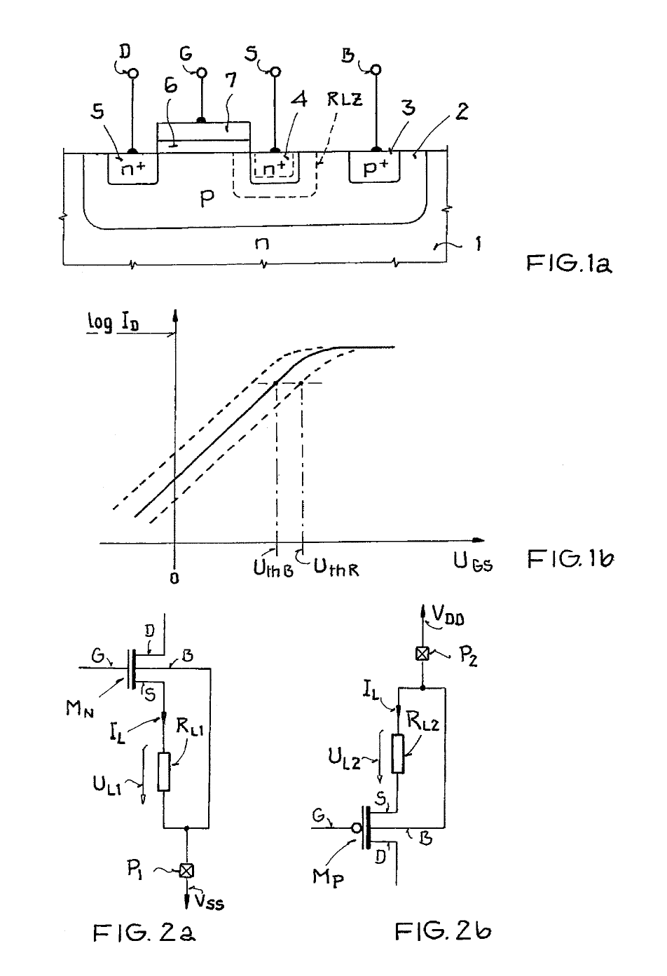

A MOS field-effect transistor is shown in a schematic sectional view in FIG. 1a. A p-trough 2, which forms the body semiconductor region, is introduced within an n-doped substrate 1. A terminal semiconductor region 3 with high p-doping is provided to connect body semiconductor region 2. A drain semiconductor region 5 and a source semiconductor region 4, which have high n-doping, are arranged within the body semiconductor region 2.

A gate oxide 6 with a gate electrode 7 arranged thereupon is arranged on the surface between drain region 5 and source region 4. The p-doped semiconductor material of body semiconductor region 2 extends below gate oxide 6 between drain region 5 and source region 4. The terminals drain D, gate G, source S, and body B are provided to connect the MOS field-effect transistor. In an operating mode, a positive voltage, compared with body semiconductor region 2, can be applied at gate G, and it induces a channel below gate oxide 6. In this case, the MOS field-effect transistor conducts and has a low-resistance drain-source path. If the gate G is at the source potential, the transistor blocks.

In the sleep mode, either the NMOS field-effect transistor shown in FIG. 1a or a PMOS field-effect transistor, connected in series with said transistor, blocks. For the following discussion, it is assumed that the NMOS field-effect transistor, as it is depicted in FIG. 1a, blocks and therefore determines the leakage current through the series connection comprising the PMOS field-effect transistor and said NMOS field-effect transistor. In this case, gate-electrode 7 is at the same potential as source S. If the body B also has the same potential as source S, semiconductor regions 3 and 4 are therefore at the same potential level.

The leakage current through the MOS field-effect transistor according to FIG. 1a can be divided into two parts. The smaller part is produced by charge carrier generation in a space charge region spreading around drain semiconductor region 5 (not shown in FIG. 1). The larger leakage current part, however, flows under gate oxide 6 at the interface between the semiconductor material and oxide from drain semiconductor region 5 into source semiconductor region 4.

If the source potential in semiconductor region 4 is increased compared with the body potential in semiconductor region 2, a space charge region RLZ forms around semiconductor region 4 of the source S; it also extends under gate oxide 6 below gate electrode 7 in body semiconductor region 2. Because of the increasing voltage drop between body B and source S, the space charge region RLZ under gate oxide 6 is larger.

After removal of the holes to body-terminal semiconductor region 3, therefore, the number of the fixed charges (E-ions) increases. For charge neutrality, accordingly, the charge for the same gate source voltage decreases in an area of the space charge region RLZ below gate oxide 6. This is also called a body effect.

It is shown in FIG. 1b that the body effect causes an increase in the threshold voltage Uₜₕ from a threshold voltage value in the operating mode U_{thB} to a threshold voltage value in the sleep mode U_{thR}. Furthermore, in FIG. 1b a characteristic for the logarithmic value of the drain current I_{D} is shown with respect to the gate voltage U_{GS}. In so doing, it is desirable that in the operating mode the threshold voltage U_{thB} is not increased. In contrast, in the sleep mode at a gate-source voltage of 0 volts, the drain current I_{D} should be considerably reduced.

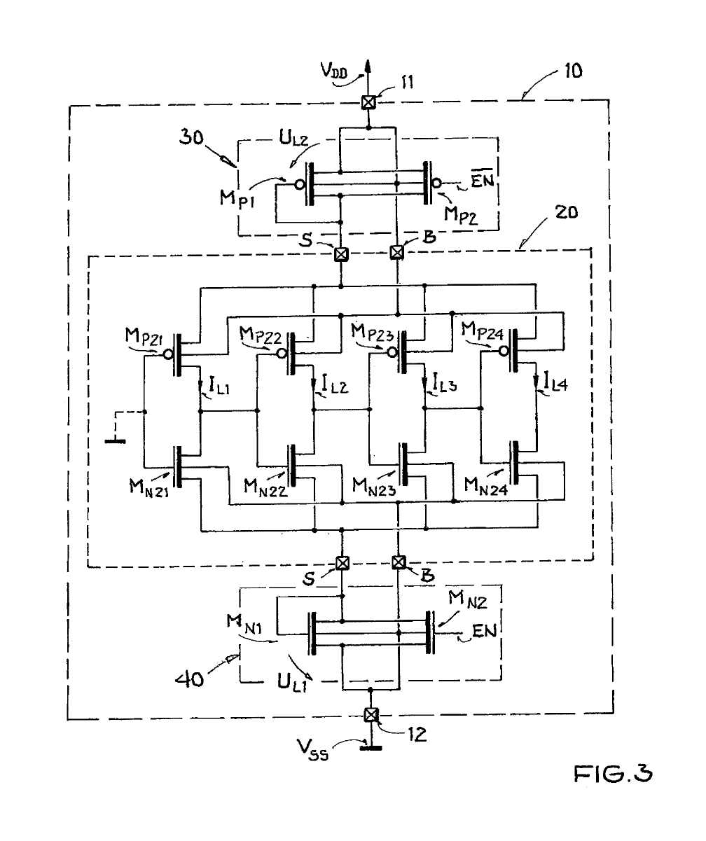

FIG. 2a shows the basic principle of a load device for a leakage current through an NMOS transistor MN corresponding to the NMOS transistor of FIG. 1a. In this case, the source terminal S of the NMOS field-effect transistor MN is connected to a load device RL1. Said load device RL1 is moreover connected to a supply voltage VSS via a terminal P1. Terminal P1 is, for example, a PAD structure of the semiconductor circuit. The body terminal B of the NMOS field-effect transistor MN as well is connected to the supply voltage VSS.

The leakage current flowing across the body terminal B is disregarded in this exemplary embodiment, because it is significantly exceeded by the leakage current of the source S, which also flows through the load device RL1. Load device RL1 is a resistor, for example. Leakage current IL, which flows through the load device RL1, in so doing produces a voltage drop UL1 across the load device RL1. The voltage drop UL1 across load device RL1 accordingly produces two different potentials at the body terminal B and at the source terminal S of NMOS field-effect transistor MN. As already described in regard to FIG. 1a, this potential difference between the source terminal S and the body terminal B produces a space charge region around source semiconductor region 4.

The surprising effect can be achieved by means of this arrangement for the sleep mode that the leakage current IL through the source S is reduced by up to 80% as a function of the geometry of the NMOS field-effect transistor MN and the produced potential difference between source S and body B. The exemplary embodiment of FIG. 2a is only schematic here, because for a sufficient potential difference between source S and body B a summation of a plurality of leakage currents of a large plurality of NMOS field-effect transistors is necessary; in this regard, individual leakage currents are summed, for example, in a current node, which is connected conductively to load device RL1.

FIG. 2b shows a complementary version of a load device RL2 for the leakage current IL through the source S of a PMOS field-effect transistor MP. The load device RL2 is again connected to the source S of the field-effect transistor MP and a supply voltage VDD. In addition, the body terminal of the PMOS field-effect transistor MP is connected to the same supply voltage VDD. Leakage current IL through the source S again causes a voltage drop UL2 at the load device RL2 which leads to a potential difference between source S and body B. In the case of the PMOS field-effect transistor MP as well, a space charge region, which enables a reduction of the leakage current by, for example, 80%, forms around its (p-doped) source semiconductor region.

A schematic exemplary embodiment for a circuit 10 with a digital CMOS circuit 20 and a first load device 40 and a second load device 30 is shown schematically in FIG. 3. First load device 40 is connected to all source terminals S and all body terminals B of NMOS field-effect transistors MN21, MN22, MN23, and MN24 of digital CMOS circuit 20. Furthermore, first load device 40 is connected via pad 12 to a first supply voltage VSS, which is lower than a second supply voltage VDD, connected to pad 11. For example, the first supply voltage VSS is a negative voltage or ground.

Second load device 30, in contrast, is connected to the second supply voltage VDD via pad 11. The second supply voltage VDD is, for example, a positive supply voltage. Furthermore, second load device 30 is connected to all source terminals S of PMOS field-effect transistors MP21, MP22, MP23, and MP24 of CMOS circuit 20. In addition, second load device 30 is connected to all body terminals B of PMOS field-effect transistors MP21, MP22, MP23, and MP24 of CMOS circuit 20.

PMOS field-effect transistors MP21, MP22, MP23, and MP24 have body terminals B, which are connected directly to the second supply voltage VDD. NMOS field-effect transistors MN21, MN22, MN23, and MN24 have a body terminal B, which is connected directly to the first supply voltage VSS.

NMOS field-effect transistor MN1 of first load device 40, in this respect, acts as a load device according to the resistor RL1 shown in FIG. 2a. In this case, the gate of the NMOS field-effect transistor MN1 of first load device 40 is connected to the drain terminal of the NMOS field-effect transistor MN1 of first load device 40. As a result, the NMOS field-effect transistor MN1 has a nonlinear characteristic, which at low currents through the NMOS field-effect transistor MN1 causes a voltage drop >0.1 volts. In the example illustrated in FIG. 3, in the sleep mode, only a leakage current flows through the NMOS field-effect transistor MN1, which is the first load device 40, whereby the same leakage current flows through the digital CMOS circuit. Only this leakage current generates a first voltage drop UL1 on the first load device 40. Thereby, the voltage drop UL1 is generated by the leakage current to reduce the leakage current so that no additional current is needed to generate the voltage drop.

This voltage drop in the sleep mode is responsible for the fact that the leakage current through digital CMOS circuit 20, and therefore through NMOS field-effect transistors MN21, MN22, MN23, and MN24 of digital CMOS circuit 20, is significantly reduced by the potential difference between the source terminal S and the body terminal B. The potential difference, in this case, is caused by the voltage drop UL1 across the NMOS field-effect transistor MN1 of first load device 40.

This voltage drop UL1, in contrast, is not desirable in the operating mode, so that first load device 40 has another NMOS field-effect transistor MN2, which acts as a switch element and in the switched-on state short-circuits the drain-source path of the NMOS field-effect transistor MN1 acting as a resistance element. To this end, a logic one or a high signal is applied at the control input EN of NMOS field-effect transistor MN2 acting as the switch element.

Corresponding to first load device 40, second load device 30 is formed as complementary. The PMOS field-effect transistor MP1 as a resistance element in so doing in the sleep mode produces a voltage drop UL2, which increases the potential at body B compared with the potential at the source S of PMOS field-effect transistors MP21, MP22, MP23, and MP24 of the digital CMOS circuit. In the example illustrated in FIG. 3, in the sleep mode, only a leakage current flows through the PMOS field-effect transistor MP1, which is the second load device 30, whereby the same leakage current flows through the digital CMOS circuit. Only this leakage current generates a second voltage drop UL2 on the second load device 30. Thereby, the voltage drop UL2 is generated by the leakage current to reduce the leakage current so that no additional current is needed to generate the voltage drop.

In the schematic exemplary embodiment of FIG. 3, for example, PMOS transistors MP22 and MP24 block, so that the current through the PMOS transistor MP1, acting as a resistance element, of the second load device 30 is determined by the sum of leakage currents IL2 and IL4. In contrast, leakage currents IL1 and IL2 through the NMOS transistors MN21 and MN23 determine the current through the NMOS field-effect transistor MN1, acting as resistance element, of first load device 40.

For the operating mode, a control signal is applied at the NMOS field-effect transistor MN2, acting as the switch element, of first load device 40 and an inverted control signal at the control input EN of the PMOS field-effect transistor MP2, acting as a switch element, of second load device 30, so that the resistance elements MP1 and MN1 are each short-circuited.

The voltage drops UL1 and UL2, which occur in the sleep mode, across the NMOS field-effect transistor MN1 or the PMOS field-effect transistor MP1 must be designed in such a way that the resulting voltage drop across digital CMOS circuit 20 is sufficiently high, so that the high level and low level within the digital CMOS circuit 20 are reliably defined in the sleep mode.

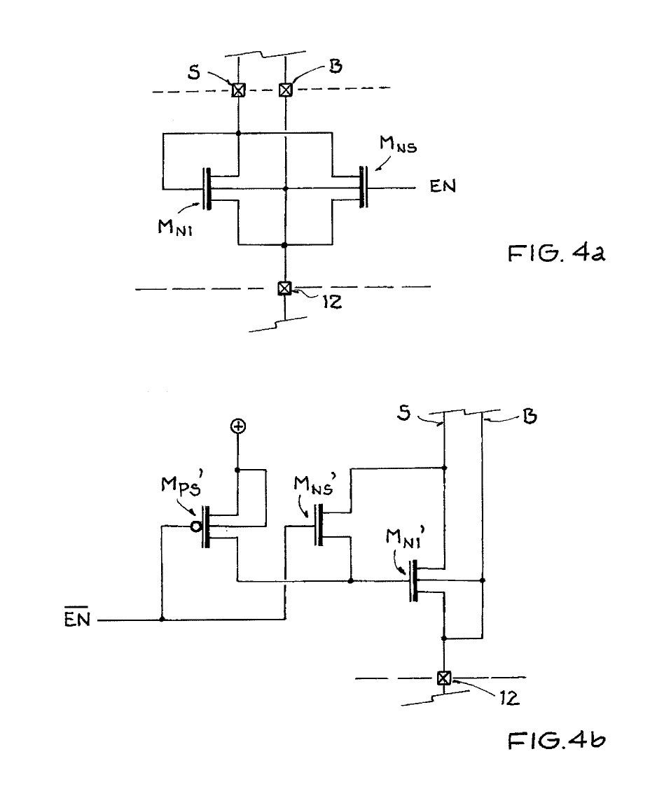

FIG. 4a in a schematic depiction shows a first exemplary embodiment of a load device with NMOS field-effect transistors MN1 and MNS, as are used analogous to FIG. 3. In contrast, FIG. 4b shows an alternative exemplary embodiment of a load device with an NMOS field-effect transistor MN1′ as a variable resistance device.

In contrast to the exemplary embodiment of FIG. 4a, in the exemplary embodiment of FIG. 4b, the gate terminal of the NMOS field-effect transistor MN1′ and the drain terminal of the NMOS field-effect transistor MN1′ are not directly connected but via a switching transistor MNS′. Furthermore, the gate terminal of the NMOS field-effect transistor MN1′, acting as a variable resistance device, is connected via another switching transistor MPS′ to the positive supply voltage.

This circuit configuration of FIG. 4b has the effect that at a low signal at the control input EN the positive supply voltage by means of the additional semiconductor switch MPS′ is switched to the gate electrode of the NMOS field-effect transistor MN1 acting as a variable resistance device and switches it to a low-resistance state, so that the source terminals of digital CMOS circuit 20 are connected directly to the supply voltage VSS in the operating mode. If in contrast in the sleep mode a high signal is applied at the control input EN, the switching transistor MNS′ switches through, whereas the other switching transistor MPS′ blocks, so that the drain terminal and gate terminal of the NMOS field-effect transistor MN1′, acting as a variable resistance device, are connected to one another via the switching transistor MNS′.

The invention, however, is not limited to the shown embodiment variants in FIGS. 1a through 4b. For example, it is possible to use a different digital circuit type with an accordingly low quiescent current instead of the CMOS circuit. A digital circuit can also be provided with exclusively NMOS transistors or exclusively PMOS transistors. Instead of the digital CMOS circuit 20, shown in FIG. 3, a circuit with a much higher number of logic functions, gates, and memory elements such as flip-flops or latches can be used.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A circuit comprising:
a digital CMOS circuit with NMOS field-effect transistors and with PMOS field-effect transistors;
a first load device, wherein source terminals of the NMOS field-effect transistors of the digital CMOS circuit are connectable via the first load device to a first supply voltage; and
a second load device, wherein source terminals of the PMOS field-effect transistors of the digital CMOS circuit are connectable via the second load device to a second supply voltage,
wherein body terminals of the NMOS field-effect transistors of the digital CMOS circuit are connected directly to the first supply voltage, and
wherein body terminals of the PMOS field-effect transistors of the digital CMOS circuit are connected directly to the second supply voltage.

2. The circuit according to claim 1, wherein the digital CMOS circuit is formed for an operating mode and for a sleep mode.

3. The circuit according to claim 1, wherein the first load device and the second load device each have a variable resistance device or a switchable resistor.

4. The circuit according to claim 3, wherein the variable resistance device has at least one field-effect transistor.

5. The circuit according to claim 3, wherein the variable resistance device, at least in a sleep mode, has a nonlinear resistance value.

6. The circuit according to claim 3, wherein the variable resistance device is formed by a field-effect transistor whose gate terminal and drain terminal is connectable conductively to one another.

7. The circuit according to claim 3, wherein the variable resistance device has a resistance element and a switching element connected in parallel, which short-circuits the resistance element in an operating mode.

8. The circuit according to claim 2, wherein the first load device and the second load device have a higher resistance value in the sleep mode than in the operating mode.

9. The circuit according to claim 2, wherein the digital circuit has a number of memory elements and/or a number of logic elements, and wherein the first load device and the second load device and the memory elements and/or logic elements are formed in such a way that the information in the memory elements and/or the logic states of the logic elements are retained in the sleep mode.

10. The circuit according to claim 1, wherein the first load device is configured to generate a first voltage drop via only a leakage current that flows through the digital CMOS circuit and the first load device.

11. The circuit according to claim 1, wherein the second load device is configured to generate a second voltage drop via only a leakage current that flows through the digital CMOS circuit and the second load device.

12. A method for a circuit with MOS field-effect transistors for controlling the circuit in an operating mode and in a sleep mode with a current consumption that is reduced compared with the operating mode, the method comprising:
controlling, in the operating mode, a load device connected to source terminals of the MOS field-effect transistors to a low-resistance state, and
controlling, in the sleep mode, the load device in a state with a higher resistance value such that a leakage current flowing in the sleep mode through the MOS field-effect transistors and through the load device produces a voltage drop across the load device.

13. Use of a load device connected to source terminals of MOS field-effect transistors of a circuit to produce a body-source voltage of the MOS field-effect transistors in a sleep mode of the circuit by a leakage current flowing through the MOS field-effect transistors and through the load device and producing a voltage drop forming the body-source voltage at the load device.
